(19) United States
(12) Patent Application Publication
(10) Pub. No.: US 2003/0222270 A1
(43) Pub. Date: Dec. 4, 2003

(54) Group III nitride compound semiconductor light-emitting element

(76) Inventor: Toshiya Uemura, Nishikasugai-gun (JP)

Correspondence Address: McGinn & Gibb, PLLC, Suite 200, 8321 Old Courthouse Road, Vienna, VA, 22182-3817, US

(21) Appl. No.: 10/446,823

(22) Filed: May 29, 2003

(30) Foreign Application Priority Data
May 31, 2002 (JP) P2002-159599

(51) Int. Cl. H01L 33/00

(52) U.S. Cl. 257/99; 257/100

(57) ABSTRACT

An uppermost layer of a portion of electrodes revealed from an electrically insulating layer with which a surface of a light-emitting element is covered is formed of at least one kind of metal or an alloy of the metal selected from the group consisting of Ni, Cu, Ag, Fe and Mo, which is easy to make an alloy with solder.

The present application is based on Japanese Patent Application No. 2002-159599, which is incorporated herein by reference.

### BACKGROUND OF THE INVENTION

1. Field of the Invention

The present invention relates to a Group III nitride compound semiconductor light-emitting element. Particularly, it relates to improvement in a flip chip type Group III nitride compound semiconductor light-emitting element.

2. Description of the Related Art

A flip chip type light-emitting element is a light-emitting element having Group III nitride compound semiconductor layers laminated on a substrate. The substrate side is used as a light-emitting surface.

When the substrate is made of an electrically insulating material such as sapphire, a p-electrode and an n-electrode are formed on one surface. The side on which these electrodes are formed is used as a mount surface mounted onto a support.

For example, in accordance with Unexamined Japanese Patent Publication No. Hei. 5-13816, the flip chip type light-emitting element is mounted onto the support and electrically connected through solder bumps which are formed on the electrodes respectively and soldered to lead electrodes of the support.

On the other hand, a function of efficiently reflecting light emitted from a light-emitting layer as well as ohmic contact with a semiconductor layer is required of each of the electrodes of the flip chip type light-emitting element. Therefore, a gold alloy is being used as each of the electrodes nowadays. A gold connecting material is being used nowadays in order to stably connect such a gold alloy electrode to a lead electrode electrically and mechanically. For example, as shown in FIG. 1, the support includes a pair of lead electrode plates 1 and 2 on which stud bumps 3 and 4 made of gold balls respectively are formed so that a p-electrode and an n-electrode of a light-emitting element 5 are fusion-bonded to the stud bumps 3 and 4 while aligned with the stud bumps 3 and 4 respectively.

Each of the stud bumps 3 and 4 is formed by dropping a predetermined amount of gold onto a predetermined position of a corresponding lead electrode. For this reason, the method for forming the stud bumps 3 and 4 is complex to cause a factor of increase in the cost of production.

Therefore, the present inventor has examined measures to mechanically and electrically connect the electrodes of the flip chip type light-emitting element to lead electrodes (external electrodes) stably by using solder easy to form bumps.

### SUMMARY OF THE INVENTION

The invention is developed to solve the problem and the configuration thereof is as follows. That is,

A Group III nitride compound semiconductor light-emitting element of a flip chip type having an electrically insulating layer from which portions of electrodes are revealed, wherein an uppermost layer of each of the revealed portions of the electrodes is made of at least one kind of metal or an alloy of the metal selected from the group consisting of Ni, Cu, Ag, Fe, and Mo.

In the Group III nitride compound semiconductor light-emitting element configured as described above, solder bumps are formed on the revealed portions of the electrodes respectively. In each of the electrodes, the uppermost layer of the portion being in contact with solder is made of at least one kind of metal or an alloy of the metal selected from the group consisting of Ni, Cu, Ag, Fe, and Mo. Each of these metals is easily alloyed with Sn which is a main component of solder. Accordingly, the electrodes of the light-emitting element are mechanically and electrically stably connected to external electrodes respectively through solder. Solder bumps can be formed easily by a known method such as a flow method or a reflow method. Solder bumps can be produced easily compared with the related art using gold stud bumps, and inexpensive products can be therefore provided when such solder bumps are used.

### BRIEF DESCRIPTION OF THE DRAWINGS

In the accompanying drawings:

FIG. 1 is a view showing a related-art method for mounting a flip chip type light-emitting element;

FIG. 2 is a sectional view typically showing the layer configuration of a light-emitting element according to an embodiment of the invention;

FIG. 3 is a partly enlarged typical view showing the electrode configuration of the light-emitting element according to the embodiment;

FIG. 4 is a view showing the configuration of a round type LED in which the light-emitting element according to the embodiment is mounted;

FIG. 5 is a partly enlarged view for explaining a mount state of the light-emitting element;

FIG. 6 is a view showing the configuration of an SMD type LED in which the light-emitting element according to the embodiment is mounted;

FIG. 7 is a partly enlarged typical view showing the electrode configuration of the light-emitting element according to another embodiment of the invention; and

FIGS. 8A and 8B show the light-emitting element according to a further embodiment of the invention, FIG. 8A being a partly enlarged typical view showing the electrode configuration of the light-emitting element, and FIG. 8B being a plan view thereof.

### DETAILED DESCRIPTION OF THE PREFERRED EMBODIMENTS

The Group III nitride compound semiconductor light-emitting element according to the invention is a flip chip type light-emitting element which is formed so that Group III nitride compound semiconductor layers inclusive of a light-emitting layer are laminated on a substrate. The term “flip chip type light-emitting element” means a light-emitting element used in a flip chip type light-emitting device, that is, a light-emitting element which is mounted onto a support (such as a board, etc.) in use while the side on which a p-electrode and an n-electrode are formed is used as a mount surface. In other words, the light-emitting element according to the invention can be used for forming the flip chip type light-emitting device. In the light-emitting element according to the invention, emitted light is radiated from the substrate side, that is, the side opposite to the electrode-forming surface side.

Respective constituent members of the Group III nitride compound semiconductor light-emitting element according to the invention will be described below.

(Group III Nitride Compound Semiconductor)

Each Group III nitride compound semiconductor is represented by the general formula Al_{X}Ga_{Y}In_{1-X-Y}N (0≦X≦1, 0Y≦≦1, 0≦X+Y≦1) which includes so-called binary compounds such as AlN, GaN and InN, and so-called ternary compounds such as AlₓGa₁₋ₓN, AlₓIn₁₋ₓN and Ga_{X}In₁₋ₓN (0<x<1 in the above). The group III elements may be at least partially replaced by boron (B), thallium (Tl), or the like. The nitrogen (N) may be at least partially replaced by phosphorus (P), arsenic (As), antimony (Sb),bismuth (Bi), or the like. Each Group III nitride compound semiconductor layer may contain an optional dopant. Si, Ge, Se, Te, C, or the like, can be used as n-type impurities. Mg, Zn, Be, Ca, Sr, Ba, or the like, can be used as p-type impurities. A method for forming the Group III nitride compound semiconductor layer is not particularly limited. For example, the Group III nitride compound semiconductor layer can be formed by a known method such as a metal organic chemical vapor deposition method (MOCVD method), a molecular beam epitaxy method (MBE method), a halide vapor phase epitaxy method (HVPE method), a sputtering method, an ion-plating method or an electron showering method.

A buffer layer can be provided between the substrate and a crystal layer of the Group III nitride compound semiconductor. The buffer layer is provided for improving the crystallinity of the Group III nitride compound semiconductor grown on the buffer layer. The buffer layer can be made of a Group III nitride compound semiconductor such as AlN, InN, GaN, AlGaN, InGaN or AlInGaN.

Any substrate may be used if Group III nitride compound semiconductor layers can be grown on the substrate as well as light emitted from a light-emitting layer can be transmitted through the substrate. Examples of the material of the substrate may include sapphire, spinel, silicon carbide, and zinc oxide. Especially, a sapphire substrate can be used preferably. When the sapphire substrate is used, the face a or c of the sapphire substrate is used preferably so that Group III nitride compound semiconductor layers of good crystallinity can be grown on the substrate.

(p-Electrode)

In the flip chip type light-emitting element according to the invention, high reflectance as well as ohmic contact with a p-type semiconductor layer is required of the p-electrode. Therefore, at least one kind of metal or an alloy of the metal selected from the group consisting of Rh, Pt and Ru is preferably used as the material of a portion (junction layer) joined to the p-type semiconductor layer. Rh can be selected more preferably.

The junction layer is preferably laminated so that the allowable larger area of a surface of the p-type semiconductor layer can be covered with the junction layer. This is because a uniform electric current is injected into the p-type semiconductor layer so that a larger amount of light emitted from the light-emitting layer can be reflected. The thickness of the junction layer is preferably selected to be in a range of from 50 nm to 1000 nm.

The junction layer is preferably covered with an Au-containing layer so that up to side surfaces of the junction layer are surrounded by the Au-containing layer. The junction layer is an important layer joined to the semiconductor layer. The junction layer is provided for the double purpose of preventing the change of contact resistance and stabilizing reflectance in an interface.

To cover the whole of the junction layer for this purpose, the coating material must be a thick film. It is preferable that Au is selected as the coating material because Au is a material which is easy to form a thick film and which is stable. The thickness of the Au-containing layer is preferably selected to be in a range of from 100 nm to 2000 nm.

A first adhesive layer may be preferably provided between the Au-containing layer and the junction layer. At least one kind of metal or an alloy of the metal selected from the group consisting of Ti, V, W, Mo and Ta can be used as the material for forming the first adhesive layer. The thickness of the first adhesive layer is preferably selected to be in a range of from 5 nm to 100 nm.

At least a revealed region of the uppermost layer of the p-electrode is made of at least one kind of metal or an alloy of the metal selected from the group consisting of Ni, Cu, Ag, Fe and Mo. Each of these metals can be mechanically and electrically stably joined to solder because it is easily alloyed with Sn which is a main component of solder. The thickness of the uppermost layer is preferably selected to be in a range of from 50 nm to 3000 nm.

A barrier layer may be preferably formed between the uppermost layer and the Au-containing layer. The barrier layer prevents corrosive components such as Br contained in solder from penetrating into the electrode. At least one kind of metal or an alloy of the metal selected from the group consisting of Ti, W, Mo, V and Ta can be used as the material for forming the barrier layer. The thickness of the barrier layer is preferably selected to be in a range of from 30 nm to 500 nm.

A second adhesive layer may be preferably provided on the uppermost layer so that adhesion to an electrically insulating protective film which will be described later can be improved. At least one kind of metal or an alloy of the metal selected from the group consisting of Al, Ti, Cr, V, W and Mo can be used as the material for forming the second adhesive layer. Especially, Al or an alloy of Al can be used preferably. The thickness of the second adhesive layer is preferably selected to be in a range of from 3 nm to 100 nm.

(n-Electrode)

A metal such as Al, V, Sn, Rh, Ti, Cr, Nb, Ta, Mo, W or Hf or an alloy of two or more kinds of metals suitably selected from these metals can be used as the material of the n-electrode joined to the n-type semiconductor layer. Especially, a double-layer structure of V and Al viewed from the semiconductor layer side can be preferably used as a junction layer.

At least a revealed region of the uppermost layer of the n-electrode, like the p-electrode, is made of at least one kind of metal or an alloy of the metal selected from the group consisting of Ni, Cu, Ag, Fe and Mo. The thickness of the uppermost layer is also preferably selected to be in a range of from 50 nm to 3000 nm.

A first adhesive layer, an Au-containing layer, a barrier layer and a second adhesive layer may be further preferably provided like the p-electrode.

The materials and thicknesses of the respective layers of the n-electrode, such as the first adhesive layer, the Au-containing layer, the barrier layer and the second adhesive layer, except the junction layer are preferably selected to be equal to those of the respective layers of the p-electrode. This is for the purpose of forming respective corresponding layers simultaneously to simplify the production process.

Besides a vapor deposition method, each of the metal layers constituting these electrodes can be formed by an MBE method, a sputtering method, or any other method.

(Electrically Insulating Layer)

The electrically insulating layer is provided for covering the electrodes except partial regions to protect the electrodes and prevent a leakage current from flowing in between the electrodes. In each of the electrodes, the portion not covered with the electrically insulating layer, that is, the revealed portion of each electrode is joined to solder. The electrically insulating layer may cover the whole surface region of the light-emitting element as well as the electrodes.

The electrically insulating layer is made of a material having low wettability to solder as well as it has electrically insulating characteristic. This is for the purpose of selectively forming solder bumps on the revealed portions of the electrodes which are opening portions of the electrically insulating layer, by a known method such as a flow method or a reflow method.

If the electrically insulating layer is made of a material having high wettability and formed uniformly and continuously, there is a possibility that regions of solder to be formed on the p-electrode and the n-electrode independently may be connected to each other. When the electrically insulating film is separated in a neighbor of the p-n junction portion, regions different in surface energy can be provided so that solder bumps can be surely formed on the p-electrode and the n-electrode independently.

In other words, when a first electrically insulating layer for covering the p-electrode and a second electrically insulating layer for covering the n-electrode are provided so as to be separated from each other, the solder bump on the p-electrode and the solder bump on the n-electrode can be surely prevented from being short-circuited to each other.

However, the electrically insulating film is not necessary separated into completely separated two parts as aforementioned. The electrically insulating film may be at least partially separated by groove, etc., at a region where the n-electrode and the p-electrode are opposed and not formed.

A ceramic such as silicon oxide, silicon nitride, aluminum oxide or titanium nitride or a synthetic resin such as polyimide can be used as the electrically insulting material.

The thickness of the electrically insulating layer is preferably selected to be in a range of from 50 nm to 3000 nm.

The electrically insulating layer of the ceramic can be formed by a method such as plasma CVD, sputtering or EB vapor deposition. The electrically insulating layer of the synthetic resin can be formed by a method such as a spin coating method or a dip coating method.

A known method such as a flow method or a reflow method can be used as the method for forming solder bumps on the electrode portions revealed from the electrically insulating film. When the electrically insulating layer used is poor in wettability to solder, a method of dipping the light-emitting element into a solder bath can be merely used so that solder bumps can be formed on the revealed electrode portions.

Solder may be used in the form of stud bumps on the external electrode side. Also in this case, it is a matter of course that solder bumps are easier to form than gold stud bumps.

Embodiments of the invention will be described below.

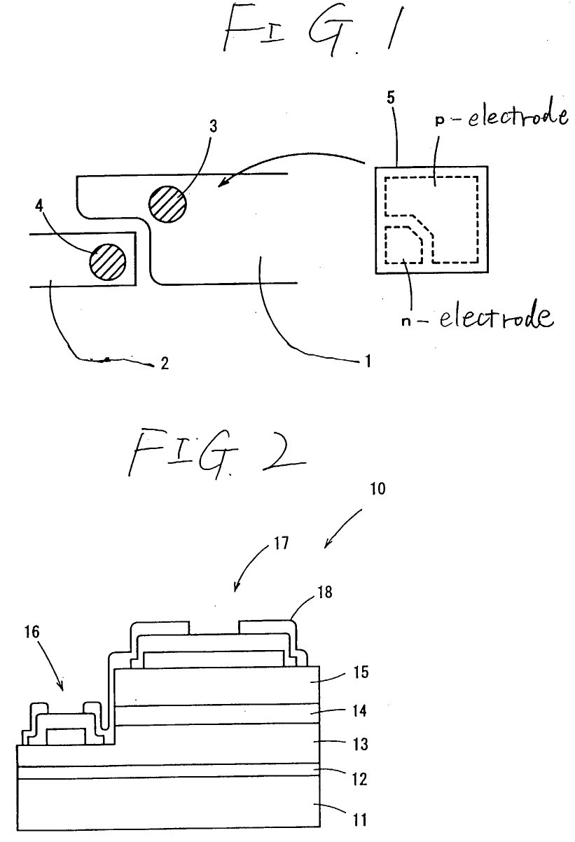

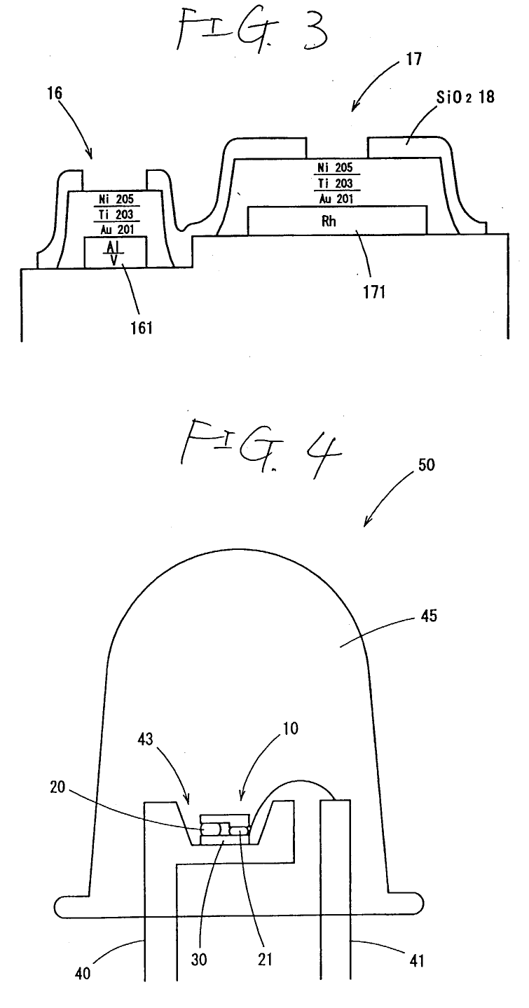

FIG. 2 is a typical sectional view of a light-emitting element 10 according to an embodiment of the invention. Specifications of respective layers of the light-emitting element 10 are as follows.

| Layer | Composition |
|---|---|
| p-type layer 15 | p-GaN:Mg |
| Layer 14 containing a | inclusive of InGaN layer |
| light-emitting layer | |
| n-type layer 13 | n-GaN:Si |
| Buffer layer 12 | AlN |
| Substrate 11 | sapphire |

An n-type layer 13 of GaN doped with Si as n-type impurities is formed on a substrate 11 through a buffer layer 12. Although the case where sapphire is used as the substrate 11 is shown here, the substrate 11 is not limited thereto. Examples of the material of the substrate 11 which can be used include sapphire, spinel, silicon carbide, zinc oxide, magnesium oxide, manganese oxide, zirconium boride, and Group III nitride compound semiconductor single crystal. Although the case where the buffer layer is formed of AlN by an MOCVD method is shown, the buffer layer is not limited thereto. Examples of the material of the buffer layer which can be used include GaN, InN, AlGaN, InGaN, and AlInGaN. The buffer layer can be formed by a method such as a molecular beam epitaxy method (MBE method), a halide vapor phase epitaxy method (HVPE method), a sputtering method, an ion-plating method or an electron showering method. When a Group III nitride compound semiconductor is used as the substrate, the buffer layer can be dispensed with.

As occasion demands, the substrate and the buffer layer may be removed after the semiconductor element is formed.

Although the case where the n-type layer 13 is made of GaN is shown here, AlGaN, InGaN or AlInGaN may be used.

Although the case where the n-type layer 13 is doped with Si as n-type impurities is shown, other n-type impurities such as Ge, Se, Te or C may be used.

The layer 14 containing a light-emitting layer may contain a quantum well structure (multiple quantum well structure or single quantum well structure). The structure of the light-emitting element may be of a single hetero type, a double hetero type or a homo junction type.

The layer 14 containing a light-emitting layer may contain a Group III nitride compound semiconductor layer disposed on the p-type layer 15 side, doped with Mg or the like and having a wide band gap. This arrangement is made for preventing electrons injected into the layer 14 containing alight-emitting layer from diffusing into the p-type layer 15.

The p-type layer 15 of GaN doped with Mg as p-type impurities is formed on the layer 14 containing a light-emitting layer. The p-type layer may be also made of AlGaN, InGaN or InAlGaN. Other p-type impurities such as Zn, Be, Ca, Sr or Ba may be used. After introduction of p-type impurities, the resistance of the p-type layer can be reduced by a known method such as electron beam irradiation, heating in a furnace or plasma irradiation.

In the light-emitting diode configured as described above, each of the Group III nitride compound semiconductor layers may be formed by an MOCVD method executed in a general condition or may be formed by a method such as a molecular beam epitaxy method (MBE method), a halide vapor phase epitaxy method (HVPE method), a sputtering method, an ion-plating method or an electron showering method.

FIG. 3 shows the detailed configuration of the electrodes. A junction layer 161 of the n-electrode 16 includes two layers of Al and V. After the p-type layer 15 is formed, the p-type layer 15, the layer 14 containing a light-emitting layer and the n-type layer 13 are partially removed by etching. The junction layer 161 is formed on the n-type layer 13 by vapor deposition. The thickness of the V layer is 20 nm. The thickness of the Al layer is 1500 nm.

Then, a junction layer 171 of Rh in the p-electrode 17 is formed on the p-type layer 15 by vapor deposition. The thickness of the junction layer 171 is 300 nm.

Successively, alloying is made by a known method. Then, a layer 201 of Au, a layer 203 of Ti (barrier layer) and an uppermost layer 205 of Ni are formed on each of then-type junction layer 161 and the p-type junction layer 171 by vapor deposition so that each of the junction layers 161 and 171 is covered with the layers 201, 203 and 205 which are 10 nm, 1500 nm and 300 nm thick respectively.

Then, an electrically insulating layer 18 of SiO₂ is formed on the nearly whole surface of the light-emitting element by a plasma CVD method. The thickness of the electrically insulating layer 18 is selected to be 150 nm.

Opening portions for revealing the upper surfaces of the electrodes 16 and 17 respectively are formed in the electrically insulating layer 18. Solder bumps are formed on the opening portions as follows. After flux is applied on the surface of the light-emitting element, the light-emitting element is dipped into a solder bath. Because the electrically insulating layer 18 for covering the surface of the element is poor in wettability to solder, solder is collected into the portions where the electrically insulating layer is not formed, that is, into the revealed electrode portions. Thus, bumps are formed.

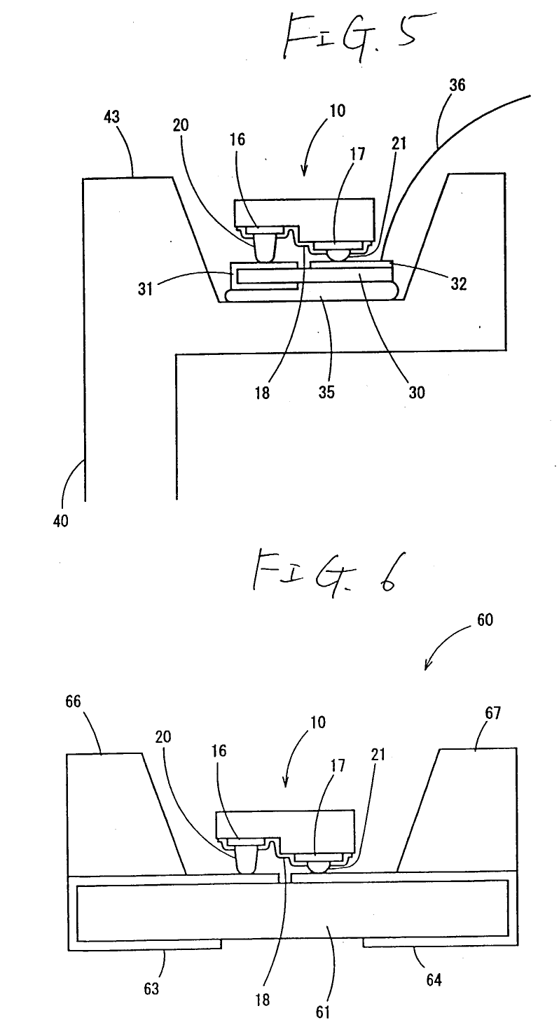

As shown in FIG. 4, the light-emitting element having the solder bumps 20 and 21 is fixed onto a support 30 while the electrode surface faces down. The support 30 is fixed into a cup portion 43 of a mount lead 40.

FIG. 5 shows the detailed assembling structure of the light-emitting element 10. The support 30 has a first lead electrode 31, and a second lead electrode 32. The first lead electrode 31 is electrically connected to a lead frame 43 through an electrically conductive paste member 35. The second lead electrode 32 is electrically connected to a lead frame 41 through a wire lead 36. Each of these lead electrodes 31 and 32 is made of Cu easy to be alloyed with materials of solder. Each of the lead electrodes may be made of at least one kind of metal or an alloy of the metal selected from the group consisting of Au, Ni, Ag, Fe and Mo, besides Cu.

The solder bump 20 of the n-electrode 16 abuts on the first lead electrode 31. The solder bump 21 of the p-electrode 17 abuts on the second lead electrode 32. When heated in this state, the solder bumps 20 and 21 are alloyed with the uppermost layers 205 of the electrodes 16 and 17 and with the lead electrodes 31 and 32 respectively. As a result, firm mechanical connection and firm electrical connection are formed between the n-electrode 16 and the first lead electrode 31 and between the p-electrode 17 and the second lead electrode 32, respectively.

The light-emitting element 10 and the lead members 40 and 41 mounted thus in the form of a flip chip type are covered with a round type sealing member 45 as shown in FIG. 4. Thus, a light-emitting device (LED) 50 is produced.

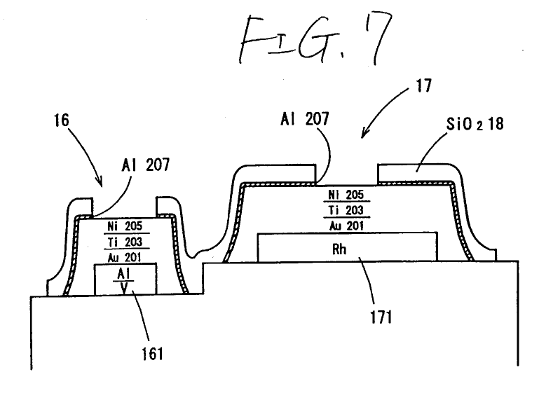

FIG. 6 shows an example in which the light-emitting element 10 is assembled into an SMD type LED 60. Incidentally, parts the same as those in FIG. 5 are referred to by numerals the same as those in FIG. 5 and the description of the parts will be omitted.

The LED 60 includes the light-emitting element 10, aboard 61, and reflecting members 66 and 67. A first lead electrode 63 and a second lead electrode 64 are formed on the board 61. The respective lead electrodes are wired to a master board not shown.

Also in this example, the solder bump 20 of then-electrode 16 abuts on the first lead electrode 63 while the solder bump 21 of the p-electrode 17 abuts on the second lead electrode 64. When heated in this state, the solder bumps 20 and 21 are alloyed with the uppermost layers 205 of the electrodes 16 and 17 and with the lead electrodes 63 and 64 respectively. As a result, firm mechanical connection and firm electrical connection are formed between the n-electrode 16 and the first lead electrode 63 and between the p-electrode 17 and the second lead electrode 64, respectively.

Also in the SMD type LED, the light-emitting element 10 can be covered with a sealing material.

FIG. 7 shows the configuration of electrodes of the light-emitting element according to another embodiment of the invention. Parts the same as those in FIG. 3 are referred to by numerals the same as those in FIG. 3 and the description of the parts will be omitted. Like the light-emitting element shown in FIG. 3, this light-emitting element can be used for the LEDs shown in FIGS. 5 and 6.

In this embodiment, a second adhesive layer 207 of Al is interposed between the uppermost layer 205 of each of the electrodes 16 and 17 and the electrically insulating layer 18. The second adhesive layer 207 is formed by vapor deposition and 10 nm thick.

The interposition of the Al layer improves adhesion between each electrode and the electrically insulating layer. Furthermore, when dry etching (plasma etching) is performed to provide opening portions as revealed portions of the electrodes in the electrically insulating layer of SiO₂, damage of layers under the Al layer can be prevented if the Al layer highly resistant to dry etching is on the surface of each electrode. Accordingly, preferable junction between solder and the uppermost layer of each electrode can be ensured.

It is therefore preferable that the whole surface of the electrodes is first covered with the Al layer, and that the revealed portions of the Al layer are removed from the opening portions by wet etching or dry etching after the opening portions are formed in the electrically insulating layer.

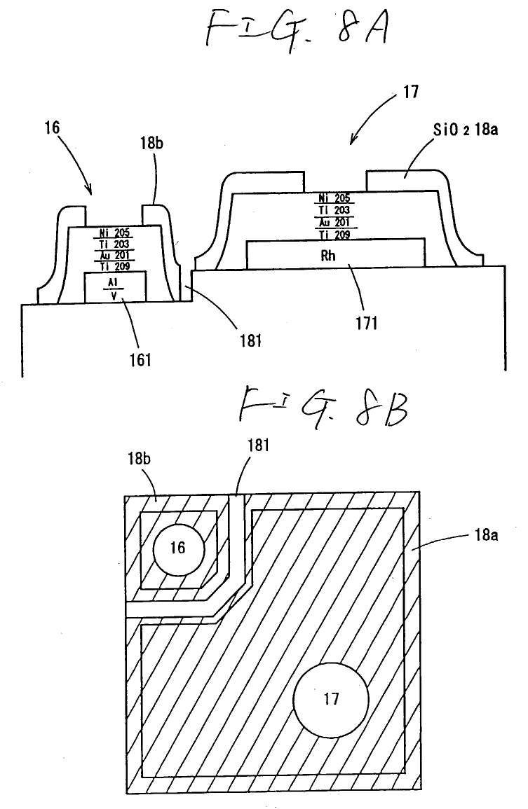

FIGS. 8A and 8B show the configuration of electrodes of the light-emitting element according to a further embodiment of the invention. Parts the same as those in FIG. 3 are referred to by numerals the same as those in FIG. 3 and the description of the parts will be omitted. Like the light-emitting element shown in FIG. 3, this light-emitting element can be used for the LEDs shown in FIGS. 5 and 6.

In this embodiment, a layer 209 of Ti is interposed between each of the junction layers 171 and 161 and the Au layer 201. The Ti layer 209 (first adhesive layer) is formed by vapor deposition and 50 nm thick.

This layer 209 can further prevent corrosive components such as Br contained in solder from penetrating into the electrodes. As a result, both reliability and durability of the LED are improved.

Also in this embodiment, a second adhesive layer can be interposed between the uppermost layer and the electrically insulating layer in the same manner as in FIG. 7.

In this embodiment, the electrically insulating layer is separated in a neighbor of the p-n junction portion (step portion). Because the electrically insulating layer is separated into a portion 18a for covering the p-electrode and a portion 18b for covering the n-electrode, the solder bump on the p-electrode and the solder bump on the n-electrode can be surely prevented from being connected to each other.

The partition groove 181 of the electrically insulating layer can be also formed in examples shown in FIGS. 3 and 7.

The present invention is not limited to the description of the mode for carrying out the invention and the embodiments thereof at all, but includes various modifications that can be easily conceived by those skilled in the art, without departing from the scope of claim for a patent.

The following item is disclosed.

A method of producing a light-emitting device, including the steps of:

preparing a Group III nitride compound semiconductor light-emitting element of a flip chip type, comprising an electrically insulating layer from which a portion of an electrode is revealed, wherein an uppermost layer of said revealed portion of said electrode is made of at least one kind of metal or an alloy of the metal selected from the group consisting of Ni, Cu, Ag, Fe, and Mo;

forming solder bumps on revealed electrode portions of the Group III nitride compound semiconductor light-emitting element; and

soldering the solder bumps to external electrodes while making the solder bumps abut on the external electrodes.

What is claimed is:

1. A Group III nitride compound semiconductor light-emitting element of a flip chip type, comprising an electrically insulating layer from which a portion of an electrode is revealed, wherein an uppermost layer of said revealed portion of said electrode is made of at least one kind of metal or an alloy of the metal selected from the group consisting of Ni, Cu, Ag, Fe, and Mo.

2. A Group III nitride compound semiconductor light-emitting element according to claim 1, wherein a barrier layer for preventing a corrosive component contained in solder from penetrating into each of said electrodes is formed under said uppermost layer.

3. A Group III nitride compound semiconductor light-emitting element according to claim 2, wherein said barrier layer is made of at least one kind of metal or an alloy of the metal selected from the group consisting of Ti, W, Mo, V, and Ta.

4. A Group III nitride compound semiconductor light-emitting element according to claim 2, wherein a layer containing Au is formed under said barrier layer and surrounds a junction layer electrically joined to a semiconductor layer.

5. A Group III nitride compound semiconductor light-emitting element according to claim 4, wherein said junction layer is made of Rh and joined to a p-type semiconductor layer.

6. A Group III nitride compound semiconductor light-emitting element according to claim 4, wherein said junction layer is made of an alloy of Al and V or a double-layer structure of V and Al, and joined to an n-type semiconductor layer.

7. A Group III nitride compound semiconductor light-emitting element according to claim 1, wherein an adhesive layer is interposed between said uppermost layer and said electrically insulating layer.

8. A light-emitting device comprising:
a Group III nitride compound semiconductor light-emitting element according to one of claims 1 to 7; and
an external electrode, wherein the revealed portion of said electrode of said light-emitting element is connected to said external electrode through solder.

9. A Group III nitride compound semiconductor light-emitting element comprising:
a substrate;
n-type and p-type layers laminated on said substrate;
a combination of an n-electrode and a p-electrode disposed on a surface side of said substrate; and
an electrically insulating film with which said light-emitting element except a portion of said n-electrode and the p-electrode are covered,
wherein said electrically insulating film is at least partially separated at a region where said n-electrode and said p-electrode are opposed and not formed.
